(19) United States
(12) Patent Application Publication
(10) Pub. No.: US 2026/0371999 A1
(43) Pub. Date: Nov. 19, 2026

(54) CONTAINER FOR SEMICONDUCTOR WAFERS WITH SOFT LANDINGS AND SAFE STORAGE

(71) Applicant: Taiwan Semiconductor Manufacturing Co., Ltd., Hsinchu (TW)

(72) Inventors: Jen-Yuan CHANG, Hsinchu (TW); Yi-Chen LI, Hsinchu (TW)

(73) Assignee: Taiwan Semiconductor Manufacturing Co., Ltd., Hsinchu (TW)

(21) Appl. No.: 19/755,282

(22) Filed: Jul. 27, 2026

Related U.S. Application Data
(62) Division of application No. 18/965,607, filed on Dec. 2, 2024.

(51) Int. Cl. H10P 72/10

(52) U.S. Cl. CPC H10P 72/1912; H10P 72/1911

(57) ABSTRACT

One or more bracket structures within a workpiece container configured to, in operation, receive one or more workpieces (e.g., unprocessed wafers, partially processed wafers, wafer assemblies, etc.). Each respective bracket structure of the one or more bracket structures includes a plurality of recesses configured to, in operation, receive the one or more workpieces. At least one of the recesses of each of the respective bracket structures is partially lined with a soft material, which may be an elastic material. The soft material acts as a bumper or support to prevent mechanical defects (e.g., scratching, micro-cracking, cracking, or some other similar or like mechanical defect) from propagating at, along, or within the workpiece when present within the respective recesses lined with the soft material.

### PRIORITY CLAIM

This application is a divisional of U.S. patent application Ser. No. 18/965,607, filed on Dec. 2, 2024, which is incorporated by reference herein in its entirety.

### BACKGROUND

Containers are utilized to hold and store semiconductor wafers. These containers are generally configured to, in operation of the FAB (i.e., semiconductor manufacturing plant), be transported between various locations within the FAB. One or more of the semiconductor wafers present within the containers are removed from the containers and received by processing tools such that the semiconductor wafers are processed and refined into semiconductor devices (e.g., semiconductor chips, semiconductor dice, or some other similar or like type of semiconductor device). These containers are generally known as FOUPs (i.e., Front Opening Universal Pods) or cassettes and are configured to, in operation, contain one or more workpieces (e.g., unprocessed wafers, partially processed wafers, processed wafers, partially or fully processed wafer assemblies, or some other similar or like type of workpiece being processed by the FAB). These FOUPs or cassettes are generally configured to, in operation, contain one or more semiconductor wafers that are either inserted or removed from the FOUPs or cassettes for storage purposes, transportation purposes, and processing purposes of the one or more semiconductor wafers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a conventional FOUP known within the semiconductor industry.

FIG. 1B is a cross-sectional view of the conventional FOUP as shown in FIG. 1A taken along line 1B-1B as shown in FIG. 1A.

FIG. 1C is a cross-sectional view of the conventional FOUP as shown in FIG. 1C taken along line 1C-1C as shown in FIGS. 1A and 1B.

FIG. 2 is a zoomed in, enhanced view of section A-A as shown in FIG. 1C of a respective workpiece inserted into a bracket of the conventional FOUP as shown in FIGS. 1A-1C.

FIG. 3 is a zoomed in, enhanced view of section A-A as shown in FIG. 1C of a respective workpiece inserted into the bracket of the conventional FOUP as shown in FIGS. 1A-1C.

FIG. 4 is a zoomed in, enhanced view of section A-A as shown in FIG. 1C of a respective workpiece inserted into the bracket of the conventional FOUP as shown in FIGS. 1A-1C.

FIG. 5A is a perspective view of a FOUP, in accordance with some embodiments.

FIG. 5B is a cross-sectional view of the FOUP as shown in FIG. 5A taken along line 5B-5B as shown in FIG. 5A, in accordance with some embodiments.

FIG. 5C is a cross-sectional view of the FOUP as shown in FIGS. 5A and 5B taken along line 5C-5C as shown in FIGS. 5A and 5B, in accordance with some embodiments.

FIG. 6 is a zoomed in, enhanced view of section B-B as shown in FIG. 5C of a respective workpiece inserted into a bracket of the FOUP as shown in FIGS. 5A-5C, in accordance with some embodiments.

FIG. 7 is a zoomed in, enhanced view of section B-B as shown in FIG. 5C of a respective workpiece inserted into a bracket of the FOUP as shown in FIGS. 5A-5C, in accordance with some embodiments.

FIG. 8 is a zoomed in, enhanced view of section B-B of a respective workpiece inserted into a bracket of the FOUP as shown in FIGS. 5A-5C, in accordance with some embodiments.

FIG. 9 is a cross-sectional view of a FOUP, in accordance with some embodiments.

FIG. 10 is a top plan view of a wafer assembly that is capable of being inserted into a FOUP, in accordance with some embodiments.

FIG. 11 is a cross-sectional view of the wafer assembly as shown in FIG. 10 inserted into a FOUP, in accordance with some embodiments.

FIG. 12 is a flowchart of a method of utilizing a FOUP including one or more bracket structures having recesses lined with a soft material, in accordance with some embodiments.

FIG. 13 is a flowchart of a method of manufacturing one or more bracket structures of a frame including respective surfaces covered or lined with a buffer material or layer, in accordance with some embodiments.

FIG. 14 is a zoomed in, enhanced view of a section of a bracket structure after coupling a buffer material or layer to respective surfaces of the bracket structure, in accordance with some embodiments.

FIG. 15 is a zoomed in, enhanced view of a section of a bracket structure after forming a buffer material or layer on respective surfaces of the bracket structure, in accordance with some embodiments.

FIG. 16 is a zoomed in, enhanced view of a section of a bracket structure after coupling a buffer material or layer on respective surfaces of the bracket structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

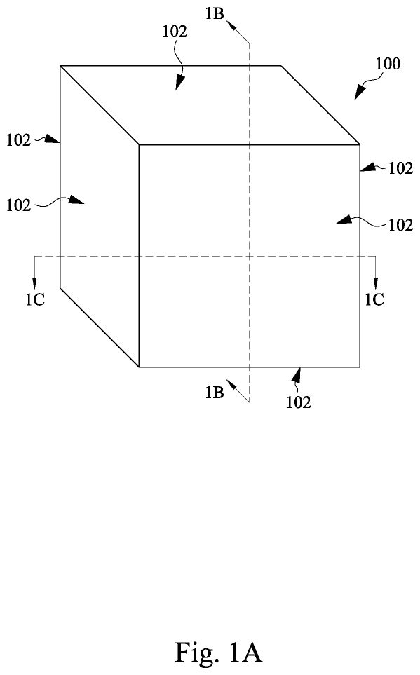

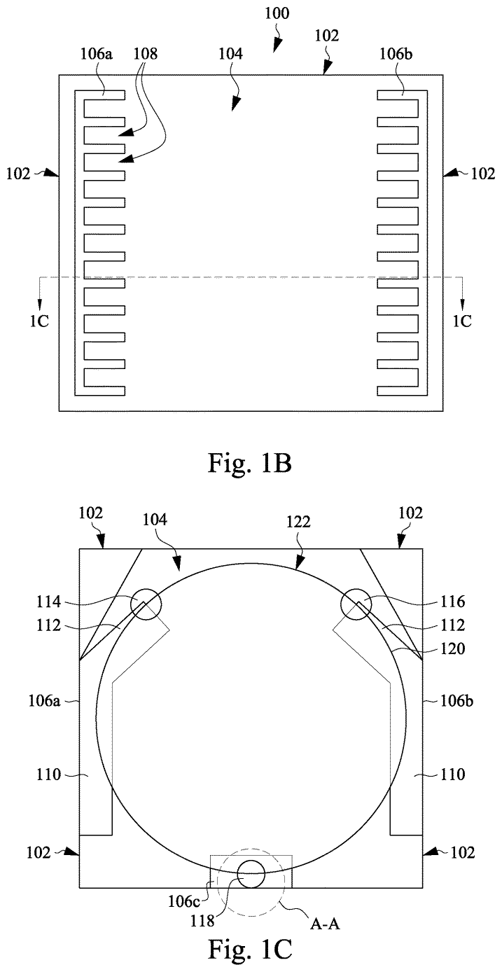

FIG. 1A is a perspective view of a conventional container 100 (e.g., a FOUP or a cassette) known to the semiconductor industry. The conventional FOUP 100 includes a plurality of sides or sidewalls 102. While not shown, an opening is present along at least one of the plurality of sides 102 such that one or more respective workpieces (i.e., wafers either fully processed, partially processed, or unprocessed), one or more respective wafer structures (i.e., either fully processed, partially processed, or unprocessed), one or more wafer assemblies (i.e., either fully processed, partially processed, or unprocessed), or some other similar or like type of structure or assembly that can be inserted into the conventional FOUP 100. The conventional FOUP 100 is configured to, in operation, receive one or more wafers, wafer structures, or wafer assemblies. These one or more wafers, the one or more wafer structures, or the one or more wafer assemblies are referred to in general as one or more workpieces that are refined and processed by the FAB (i.e., semiconductor manufacturing plant) to manufacture and output semiconductor devices.

FIG. 1B is a cross-sectional view of the conventional FOUP 100 taken along line 1B-1B as shown in FIG. 1A. A cavity 104 within the conventional FOUP 100 is lined with one or more bracket structures 106a, 106b, 106c. As shown in FIG. 1B, the first bracket structure 106a is at the left-hand side of FIG. 1B and is in close proximity to the sidewall 102 at the left-hand side of FIG. 1B, and the second bracket structure 106b is at the right-hand side of FIG. 1B and is in close proximity to the sidewall 102 at the right-hand side of FIG. 1B. The first bracket structure 106a and the second bracket structure 106b include one or more recesses 108 configured to, in operation, each receive a corresponding workpiece. In some embodiments, the first bracket structure 106a is coupled to the sidewall 102 at the left-hand side of FIG. 1B and extends outward from this sidewall 102, and the second bracket structure 106b is coupled to the sidewall 102 at the right-hand side of FIG. 1B and extends outward from this sidewall 102.

FIG. 1C is a cross-sectional view of the conventional FOUP 100 taken along line 1C-1C as shown in FIGS. 1A and 1B. While the third bracket structure 106 c is not visible at the cross-section of the conventional FOUP 100 as shown in FIG. 1B, the third bracket structure 106c is readily visible in FIG. 1C. The third bracket structure 106c has a similar structure to the first bracket structure 106a and the second bracket structure 106b in that the third bracket structure 106c includes one or more recesses 108 that are configured to, in operation, each receive a corresponding workpiece. The third bracket structure 106c is positioned between the first bracket structure 106a and the second bracket structure 106b. The first, second, and third bracket structures 106a, 106b, 106c define one or more respective shelves that are configured to, in operation, support one or more workpieces that are inserted into the one or more recesses 108 of the first, second, and third bracket structures 106a, 106b, 106c.

The first bracket structure 106a and the second bracket structure 106b have a first portion 110 and a second portion 112 that is transverse to the first portion 110. As shown in FIG. 1C, the first bracket structure 106a and the second bracket structure 106b are mirrors of each other. The first bracket structure 106a includes a first location 114, the second bracket structure 106b includes a second location 116, and the third bracket structure 106c includes a third location 118. When a workpiece 120 is inserted into corresponding recesses 108 of the first, second, and third bracket structures 106a, 106b, 106c, the workpiece 120 physically abuts the first location 114, the second location 116, and the third location 118. The workpiece 120 includes an edge 122.

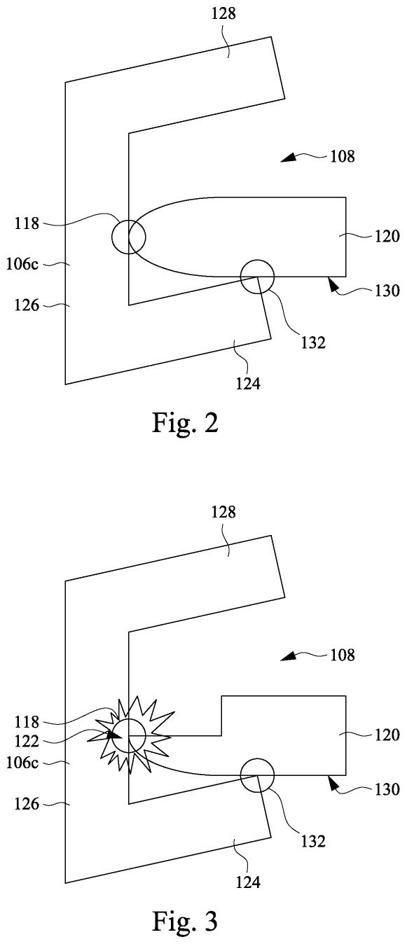

FIG. 2 is a zoomed in, enhanced view of section A-A as shown in FIG. 1C of a respective workpiece inserted into the corresponding recess 108 of the third bracket structure 106c of the conventional FOUP 100 as shown in FIGS. 1A-1C. As shown in FIG. 2, the edge 122 of the workpiece 120, which is an unprocessed wafer that has yet to undergo processing steps within the FAB, abuts the third location 118 of the third bracket structure 106c.

The third bracket structure 106c includes a first portion 124, a second portion 126, and a third portion 128. The first portion 124 and the third portion 128 are transverse to the second portion 126, and the second portion 126 extends from the first portion 124 to the third portion 128. The first portion 124 and the third portion 128 are slightly at an angle such that the corresponding recess 108 has a parallelogram profile. A surface 130 of the workpiece 120 abuts a fourth location 132 that is present at an end of the first portion 124 of the third bracket structure 106c. During this discussion of the features of the third bracket structure 106c, it will be readily appreciated that the first bracket structure 106a and the second bracket structure 106b have the corresponding recesses 108 that also receive the workpiece 120, and that the first bracket structure 106a and the second bracket structure 106b have the same or similar features as the third bracket structure 106c. Accordingly, for the sake of simplicity and brevity of the present disclosure, these similar or same features of the first bracket structure 106a and the second bracket structure 106b are not provided herein.

As the surface 130 of the workpiece 120 physically abuts the first portion 124 of the third bracket structure 106c at the fourth location 132, some scratching can occur at the surface 130 when the workpiece 120 is being transported within the conventional FOUP 100 and the conventional FOUP 100 is exposed to external forces (i.e., vibrations, bumps, or some other similar or like type of external force) resulting in the workpiece 120 within the corresponding recess 108 slightly shifting. This slight shift in the position of the workpiece 120 results in the first portion 124 at the fourth location 132 scratching the surface 130 of the workpiece 120. Similarly, as the edge 122 of the workpiece 120 physically abuts the second portion 126 of the third bracket structure 106c, some scratching can occur at the edge 122 of the workpiece 120. While scratching can occur at the surface 130 and at the edge 122 of the workpiece 120, if the external force is large enough, other types of mechanical or physical defects such as micro-cracking, cracking, or other similar or like type of defects can propagate at and along the workpiece 120. This scratching or other types of defects can cause particle buildup within the cavity 104 causing or increasing the likelihood of respective workpieces present within the cavity 104 being contaminated by these particles. These defects propagating or occurring results in a yield number of the FAB being reduced.

FIG. 3 is a zoomed in, enhanced view of section A-A as shown in FIG. 1C of a respective workpiece inserted into the corresponding recess 108 of the third bracket structure 106c of the conventional FOUP 100 as shown in FIGS. 1A-1C. As shown in FIG. 3, the edge 122 of workpiece 120, which is a partially processed wafer at which the edge 122 of the workpiece 120 has been trimmed and inserted into the conventional FOUP 100, abuts the third location 118 of the third bracket structure 106c.

As the surface 130 of the workpiece 120 physically abuts the first portion 124 of the third bracket structure 106c at the fourth location 132, some scratching can occur at the surface 130 when the workpiece 120 is being transported within the conventional FOUP 100 and the conventional FOUP 100 is exposed to external forces (i.e., vibrations, bumps, or some other similar or like type of external force) resulting in the workpiece 120 within the corresponding recess 108 slightly shifting resulting in the first portion 124 at the fourth location 132 scratching the surface 130 of the workpiece 120. Similarly, as the edge 122 of the workpiece 120 physically abuts the second portion 126 of the third bracket structure 106c, some scratching can occur at the edge 122 of the workpiece 120. While scratching can occur at the surface 130 and at the edge 122 of the workpiece 120, if the external force is large enough, other types of mechanical or physical defects such as micro-cracking, cracking, or other similar or like type of defects can propagate at and along the workpiece 120. These defects propagating or occurring results in a yield number of the FAB being reduced.

However, unlike the workpiece 120 shown in FIG. 2 that has not yet been processed such that the edge 122 of the workpiece 120 has not been trimmed or processed, the workpiece 120 shown in FIG. 3 has been trimmed such that the workpiece 120 is thinner at the edge 122. The workpiece 120 being thinner at the edge 122, as shown in FIG. 3, results in the workpiece 120 being less robust at the edge 122 than the workpiece 120 shown in FIG. 2 in which the workpiece 120 has not yet been processed at the edge 122. The edge 122 being less robust due to the thinness of the workpiece 120 at the edge 122 results in an increased likelihood of micro-cracking or cracking occurring at the edge 122 when the conventional FOUP 100 is exposed to external forces. This micro-cracking or cracking is increased as the workpiece 120 at the edge 122 is thinner, and, for example, when the workpiece 120 with the thin edge 122 is being transported within the conventional FOUP 100 and the conventional FOUP 100 is exposed to external forces resulting in the workpiece 120 within the corresponding recess 108 slightly shifting. This slight shift in the position of the workpiece 120 results in the edge 122, which has been thinned, bumping into the second portion 126 with enough force resulting in the micro-cracking or cracking of the workpiece 120. This scratching or other types of defects can cause particle buildup within the cavity 104 causing or increasing the likelihood of respective workpieces present within the cavity 104 being contaminated by these particles. These defects propagating or occurring results in a yield number of the FAB being reduced.

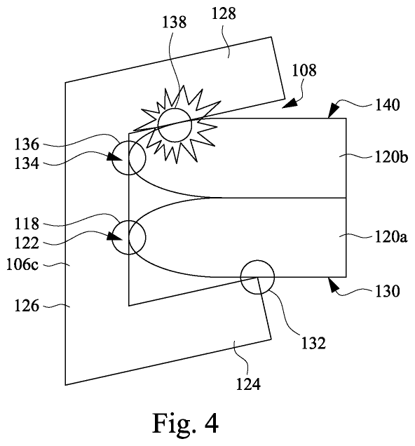

FIG. 4 is a zoomed in, enhanced view of section A-A as shown in FIG. 1C of a respective workpiece inserted into the corresponding recess 108 of the third bracket structure 106c of the conventional FOUP 100 as shown in FIGS. 1A-1C. As shown in FIG. 4, the workpiece 120, which is a wafer assembly in which a first wafer 120a has been stacked on and coupled to a second wafer 120b, abuts the third location 118 of the third bracket structure 106c.

The edge 122 of the first wafer 120a of the workpiece 120 physically abuts the second portion 126 at the third location 118. The surface 130 of the first wafer 120a of the workpiece 120 abuts the first portion 124. An edge 134 of the second wafer 120b of the workpiece 120 abuts a fifth location 136 of the second portion 126 of the third bracket structure 106c.

As the surface 130 of the workpiece 120 physically abuts the first portion 124 of the third bracket structure 106c at the fourth location 132, some scratching can occur at the surface 130 when the workpiece 120 is being transported within the conventional FOUP 100 and the conventional FOUP 100 is exposed to external forces (i.e., vibrations, bumps, or some other similar or like type of external force) resulting in the workpiece 120 within the corresponding recess 108 slightly shifting resulting in the first portion 124 at the fourth location 132 scratching the surface 130 of the workpiece 120. Similarly, as the edge 122 of the workpiece 120 physically abuts the second portion 126 of the third bracket structure 106c, some scratching can occur at the edge 122 of the workpiece 120. While scratching can occur at the surface 130 and at the edge 122 of the workpiece 120, if the external force is large enough, other types of mechanical or physical defects such as micro-cracking, cracking, or other similar or like type of defects can propagate at and along the workpiece 120. This scratching or other types of defects can cause particle buildup within the cavity 104 causing or increasing the likelihood of respective workpieces present within the cavity 104 being contaminated by these particles. These defects propagating or occurring results in a yield number of the FAB being reduced.

However, unlike the workpiece 120 shown in FIG. 2 that has not yet been processed, the workpiece 120 shown in FIG. 4 has been partially processed in which the first wafer 120a has been coupled to the second wafer 120b such that the workpiece 120 is now a wafer assembly. The workpiece 120 being the wafer assembly including the first wafer 120a and the second wafer 120b, as shown in FIG. 4, results in the second wafer 120b of the workpiece 120 potentially physically abutting the third portion 128 of the third bracket structure 106c at a sixth location 138 resulting in scratching, micro-cracking, or cracking at or in close proximity to a surface 140 of the second wafer 120b. This scratching, micro-cracking, or cracking is increased as the edge 134 of the second wafer 120b of the workpiece 120, and, for example, when the workpiece 120 with the first wafer 120a and the second wafer 120b is being transported within the conventional FOUP 100 and the conventional FOUP 100 is exposed to external forces resulting in the workpiece 120 within the corresponding recess 108 slightly shifting. This slight shift in the position of the workpiece 120, which is the wafer assembly that includes the first wafer 120a and the second wafer 120b, results in the edge 122 of the first wafer 120a bumping into the second portion 126 at the third location 118 with enough force potentially resulting in the scratching, micro-cracking, or cracking of the workpiece 120, results in the edge 134 of the second wafer 120b bumping into second portion 126 at the fifth location 136 with enough force potentially resulting in the scratching, micro-cracking, or cracking of the workpiece 120, and results in the surface 140 of the second wafer 120b bumping into the third portion 128 at the sixth location 138 with enough force potentially resulting in the scratching, micro-cracking, or cracking of the workpiece 120. These defects propagating or occurring results in a yield number of the FAB being reduced.

The present disclosure is directed to embodiments of a container, which is a FOUP or a cassette, including one or more bracket structures that are configured to, in operation, receive one or more workpieces (e.g., one or more wafers, one or more wafer structures, or one or more wafer assemblies) within the one or more bracket structures. Recesses of the one or more bracket structures that are configured to receive the one or more workpieces are each at least partially covered and lined with a soft material at locations in which the one or more wafers or wafer structures physically abut when present within the one or more bracket structures. The one or more workpieces are inserted into the bracket structures of the container (e.g., FOUP or cassette) such that these respective workpieces can be stored within the container and can be transported between locations within the container. The recesses of the bracket structures being at least partially covered and lined with the soft material at the locations in which the respective workpieces are physically abutting the bracket structures preventing or reducing the likelihood of particle contamination as discussed above with respect to FIGS. 1A-1C and 2-4, micro-cracking or cracking as discussed above with respect to FIGS. 1A-1C and 2-4, scratching as discussed above with respect to FIGS. 1A-1C and 2-4, or other similar or like type defects in view of the above discussion with respect to FIGS. 1A-1C and 2-4. As will become readily apparent in view of the discussion that follows herein, preventing or reducing the likelihood of these defects from occurring by providing the soft material at the landing locations results in an increase in a yield number of semiconductor devices that are output by a FAB (i.e., a semiconductor manufacturing plant). This increase in the yield number increases income and profit by the FAB.

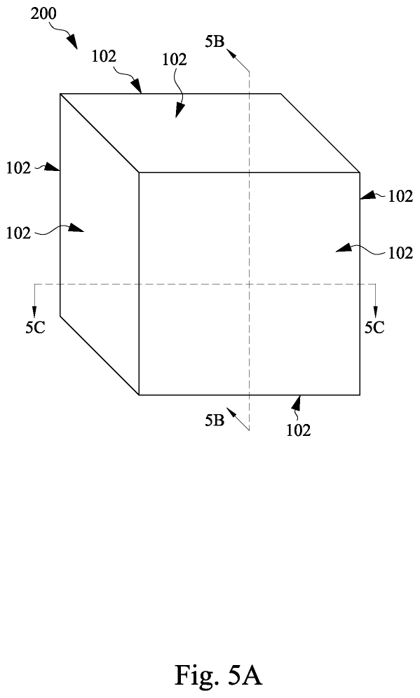

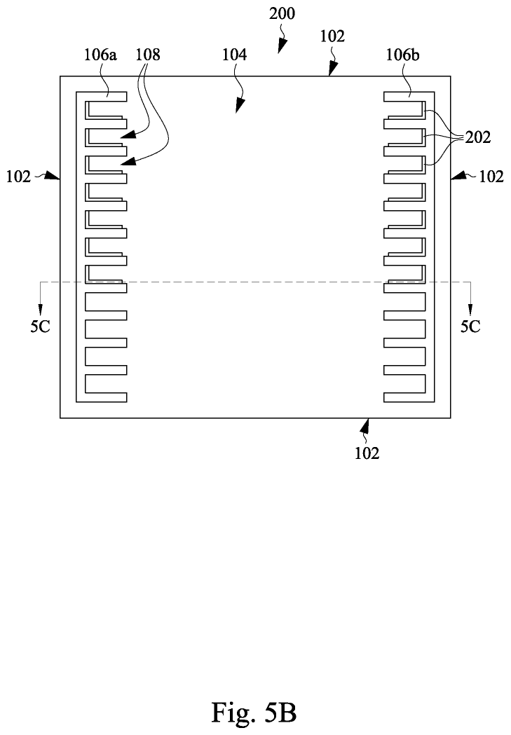

FIG. 5A is a perspective view of an embodiment of a container 200 (e.g., a FOUP or a cassette) of the present disclosure. The embodiment of the FOUP 200 has several of the same or similar features of the conventional FOUP 100 as discussed in detail earlier herein. These same or similar features of the embodiment of the FOUP 200 relative to the conventional FOUP 100 are provided with the same reference numerals. The details of these same or similar features between the embodiment of the FOUP 200 and the conventional FOUP 100 may not be reproduced in detail further herein.

While not shown, an opening is present along at least one of the plurality of sides 102 of the FOUP 200 such that one or more respective workpieces (i.e., wafers that are either fully processed, partially processed, or unprocessed), one or more respective wafer structures (i.e., either fully processed, partially processed, or unprocessed), one or more wafer assemblies (i.e., either fully processed, partially processed, or unprocessed), or some other similar or like type of structure or assembly that can be inserted into the conventional FOUP 100. The conventional FOUP 100 is configured to, in operation, receive one or more wafers, wafer structures, or wafer assemblies. These one or more wafers, the one or more wafer structures, or the one or more wafer assemblies are referred to in general as one or more workpieces that are refined and processed by the FAB (i.e., semiconductor manufacturing plant) to manufacture and output semiconductor devices.

FIG. 5B is a cross-sectional view of the FOUP 200 taken along line 5B-5B as shown in FIG. 5A. The cavity 104 within the embodiment of the FOUP 200 of the present disclosure is lined with the one or more bracket structures 106a, 106b, 106c. As shown in FIG. 5B, the first bracket structure106a is at the left-hand side of FIG. 1B, and the second bracket structure 106b is at the right-hand side of FIG. 1B. The first bracket structure 106a and the second bracket structure 106b include one or more recesses 108 configured to, in operation, each receive a corresponding workpiece. As shown in FIG. 5B, some of the one or more recesses 108 of the first bracket structure 106a and the second bracket structure 106b are lined with a buffer material or layer 202, which may be a soft and elastic material, at respective locations in which the one or more workpieces will physically abut the first bracket structure 106a and the second bracket structure 106b. In at least some embodiments, the soft and elastic material of the buffer material or layer 202 has a material hardness less than that of the one or more bracket structures 106a, 106b, 106c. In at least some embodiments, the soft and elastic material of the buffer material or layer 202 has a Young's modulus or elastic coefficient larger than that of the one or more bracket structures 106a, 106b, 106c. As shown in FIG. 5B, some of the one or more recesses 108 are not lined with the buffer material 202 such that the one or more recesses 108 that are not lined with the buffer material 202 are devoid of the buffer material 202. While not shown in FIG. 5B, it will be readily appreciated that some of the one or more recesses 108 of the third bracket structure 106c are lined with the buffer material 202 and some of the one or more recesses 108 are not lined with the buffer material 202 in a similar fashion as shown with respect to the first bracket structure 106a and the second bracket structure 106b, as shown in FIG. 5B. The positioning of the buffer material 202 at these various locations along the one or more bracket structures 106a, 106b, 106c reduces a contact area with a workpiece and distributes a contact pressure between the workpiece an the buffer material reducing the likelihood of or preventing mechanical defects from propagating or occurring within or along the workpiece. The size and shape of the buffer material 202 along the one or more bracket structures 106a, 106b, 106c can be adapted to further reduce the likelihood of or prevent mechanical defects from propagating or occurring within or along the workpeice.

In at least one situation, the respective recesses of the one or more recesses 108 that are lined with the buffer material 202 are configured to, in operation, receive a first type of workpiece, and the respective recesses of the one or more recesses 108 that are not lined with the buffer material 202 are configured to, in operation, receive a second type of workpiece. The first type of workpiece being different from the second type of workpiece. For example, in at least one situation, the first type of workpiece is a partially processed workpiece and the second type of workpiece is a yet to be processed workpiece.

The one or more recesses 108 of the first bracket structure 106a, the second bracket structure 106b, and the third bracket structure 106c that are lined with the buffer material 202 are configured to, in operation, receive various workpieces. These various workpieces may be workpieces that are more readily susceptible to scratching, micro-cracking, or cracking as discussed earlier herein with respect to the conventional FOUP 100, and, therefore, may need the presence of the buffer material 202 to provide extra protection in preventing these mechanical defects.

The one or more recesses of the first bracket structure 106a, the second bracket structure 106b, and the third bracket structure 106c that are not lined with the buffer material 202 and are devoid of the buffer material 202 are configured to, in operation, receive various workpieces. These various workpieces may be workpieces that are less susceptible to scratching, micro-cracking or cracking as discussed earlier herein with respect to the conventional FOUP 100, and, therefore, may not need the presence of the buffer material 202 to provide extra protection in preventing these mechanical defects.

By lining some of the recesses 108 of the first, second, and third bracket structures 106a, 106b, 106c with the buffer material 202 and by leaving some of the recesses 108 unlined (i.e., the buffer material 202 not being present within those recesses 108), various-sized and multiple types of workpieces, which may be at various manufacturing stages of processing by the FAB, are capable of being received by the FOUP 200 while preventing or reducing the likelihood of any mechanical defects propagating along any of the various-sized and multiple types of workpieces.

FIG. 5C is a cross-sectional view of the FOUP 200 taken along line 5C-5C as shown in FIGS. 5A and 5B. While the third bracket structure 106c is not visible at the cross-section of the embodiment of the FOUP 200 as shown in FIG. 5B, the third bracket structure 106c is readily visible in FIG. 5C. For the sake of brevity and simplicity of the present disclosure and as the details of the first bracket structure 106a, the second bracket structure 106b, and the third bracket structure 106c have been discussed in detail earlier herein, the details of the features of the first bracket structure 106a, the second bracket structure 106b, and the third bracket structure 106c may not be fully reproduced herein. Instead, the focus of the following discussion with respect to the embodiment of the FOUP 200 will focus on the additional, different, or new features of the FOUP 200 relative to the conventional FOUP 100. As set forth earlier herein, the same or similar features of the embodiment of the FOUP 200 relative to the conventional FOUP 100 are provided with the same reference numerals.

Unlike the conventional FOUP 100 as shown in FIGS. 1A-1C and 2-4, the FOUP 200 includes a plurality of portions 202a, 202b, 202c, 202d, 202e, 202f of the buffer material 202 that are at and along various locations of the first bracket structure 106a, the second bracket structure 106b, and the third bracket structure 106c.

A first portion 202a of the buffer material 202 is present at a side of the first portion 110 of the first bracket structure 106a. The first portion 202a of the buffer material 202 acts as a bumper material to reduce an impact of the edge 122 of the workpiece 120 if the workpiece 120 is slightly shifted out of place when being transported within the embodiment of the FOUP 200.

A second portion 202b of the buffer material 202 is at the end of the second portion 112 of the first bracket structure 106a. The second portion 202b of the buffer material 202 acts as a bumper material or portion at the first location 114 in which the workpiece 120 abuts and rests on the second portion 112 of the first bracket structure 106a

A third portion 202c of the buffer material 202 is at a side of the first portion 110 of the second bracket structure 106b. The third portion 202c of the buffer material 202 acts as a bumper material or portion to reduce an impact of the edge 122 of the workpiece 120 if the workpiece 120 is slightly shifted out of place when being transported within the embodiment of the FOUP 200.

A fourth portion 202d of the buffer material 202 is at the end of the second portion 112 of the second bracket structure 106b. The fourth portion 202d of the buffer material 202 acts as a bumper material or portion at the second location 116 in which the workpiece 120 abuts and rests on the second portion 112 of the first bracket structure 106a.

A fifth portion 202e of the buffer material 202 is present at a side of the third bracket structure 106c. The fifth portion 202e of the buffer material 202 acts as a bumper material or portion to reduce an impact of the edge 122 of the workpiece 120 if the workpiece 120 is slightly shifted out of place when being transported within the embodiment of the FOUP 200. In other words, the fifth portion 202e of the buffer material 202 acts as a bumper material or portion at the third location 118 in which the edge 122 of the workpiece 120 generally physically abuts the third bracket structure 106c when the workpiece is present within the embodiment of the FOUP 200.

A sixth portion 202f of the buffer material 202 is at an edge of the third bracket structure 106c. The sixth portion 202f of the buffer material 202 acts as a bumper material or portion at the fourth location 132 in which the workpiece 120 abuts and rests on the third bracket structure 106c. The sixth portion 202f of the buffer material 202 acts as a non-slip feature that prevents or reduces the likelihood of the workpiece 120 shifting within the FOUP 200 when exposed to external forces, which, in turn, prevents or reduces the likelihood of the workpiece 120 impacting the first bracket structure 106a, the second bracket structure 106b, and the third bracket structure 106c with enough force resulting in the propagation of mechanical defects (e.g., scratching, micro-cracking, cracking, or some other similar or like type of defect) at, along, or within the workpiece 120.

As discussed earlier herein, while mechanical defects (i.e., scratching, micro-cracking, cracking, or other similar or like type of mechanical defects) can propagate at and along the workpieces 120 as shown in FIGS. 2-4 when the conventional FOUP 100 is exposed to external forces, the presence of the plurality of portions 202a, 202b, 202c, 202d, 202e, 202f of the buffer material 202 prevents or reduces the likelihood of these mechanical defects propagating at and along the workpieces 120. This is because the portions 202a, 202b, 202c, 202d, 202e, 202f of the buffer material 202 are configured to, in operation, act as bumpers at these various locations at either which the edge 122 of the workpiece 120 may physically abut when the embodiment of the FOUP 200 is exposed to external forces resulting in a slight shift in the workpiece 120, or which the workpiece 120 physically abuts and rests on the first, second, and third bracket structure 106a, 106b, 106c. At least some of the plurality of portions 202a, 202c, 202e of the buffer material 202 reduce an impact of the edge 122 of the workpiece 120 against respective sides of the first, second, and third bracket structures 106a, 106b, 106c when the workpiece 120 is slightly shifted out of place, and at least some of the plurality of portions 202b, 202d, 202f of the buffer material 202 prevent or reduce the likelihood of scratching (e.g., backside scratching), which may cause particles to build up within the cavity 104, occurring along the surface 130 of the workpiece 120 that rests on the at least some of the plurality of portions 202b, 202d, 202f. In other words, the plurality of portions 202a, 202b, 202c, 202d, 202e, 202f of the buffer material 202 prevents or reduces the likelihood of mechanical defects (e.g., scratching, micro-cracking, cracking, or some other similar or like type of mechanical defects) propagating at and along the workpieces 120 as set forth above with respect to the conventional FOUP 100 such that utilizing the FOUP 200 over the conventional FOUP 100 improves a yield number output by a FAB (i.e., semiconductor manufacturing plant).

While as shown in FIG. 5C the first bracket structure 106a, the second bracket structure 106b, and the third bracket structure 106c are shown as separate and distinct bracket structures, in an alternative embodiment of the FOUP 200, the first, second, and third bracket structures 106a, 106b, 106c are replaced by a single bracket structure that extends continuously along at least three sides 102 of the FOUP 200.

The one or more bracket structures 106a, 106b, 106c may be referred together as a frame or some other similar or like type of reference.

In some embodiments, the one or more brackets structures 106a, 106b, 106c are made of a metal material. In some embodiments, the one or more bracket structures 106a, 106b, 106c are made of a plastic material. In some embodiments, the one or bracket structures 106a, 106b, 106c are made of some other suitable type of inorganic material (i.e., metal or alloy). In some embodiments, the one or more bracket structures 106a, 106b, 106c are made of some other suitable type of material.

In some embodiments, the buffer material or layer 202 is made of a rubber material. In some embodiments, the buffer material or layer 202 is made of a silicone material, In some embodiments, the buffer material or layer 202 is made of a foam material. In some embodiments, the buffer material or layer 202 is made of a leather material. In some embodiments, the buffer material or layer 202 is made of a Teflon material (e.g., polytetrafluoroethylene (PTFE) material). In some embodiments, the buffer material or layer 202 is made of a polymer compound. In some embodiments, the buffer material or layer is made of an organic based material (i.e., rubber or plastic). In some embodiments, the buffer material or layer 202 is made of some other suitable type of material.

In some embodiments, the buffer material or layer 202 is a tape material. For example, the tape material includes a buffer material on top of an adhesive such that the tape material can be adhered, coupled, or attached to various respective surfaces fo the one or more bracket structures 106a, 106b, 106c.

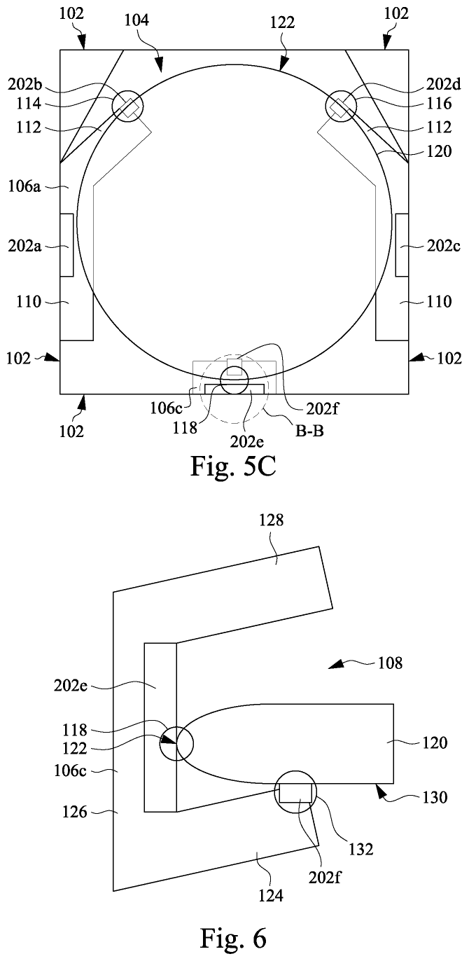

FIG. 6 is a zoomed in, enhanced view of section B-B as shown in FIG. 5C of a respective workpiece inserted into the corresponding recess 108 of the third bracket structure 106c of the FOUP 200 as shown in FIGS. 5A-5C. As shown in FIG. 6, the edge 122 of the workpiece 120, which is an unprocessed or untrimmed wafer that has yet to undergo processing steps within the FAB, abuts the third location 118 of the third bracket structure 106c. As the details of the third bracket structure 106c were described in detail earlier herein, the focus of the following discussion will be on additional, different, or new features with respect to the third bracket structure 106c as shown in FIG. 6 relative to FIG. 2.

As shown in FIG. 6, the fifth portion 202e of the buffer material 202 is present at and along the side of the second portion 126 of the third bracket structure 106c. In other words, the fifth portion 202e of the buffer material 202 lines an interior surface or sidewall of the third bracket structure 106c at the third location 118. The fifth portion 202e of the buffer material 202 acts as a bumper material or portion that reduces an impact when the workpiece 120 is slightly shifted within the FOUP 200. The sixth portion 202f of the buffer material 202 acts as a support material or portion such that the surface 130 of the workpiece 120 rests on the sixth portion 202f of the buffer material 202 preventing or reducing the likelihood of the surface 130 being scratched as the surface 130 rests on the sixth portion 202f of the buffer material 202 instead of on the first portion 124 of the third bracket structure 106c.

Furthermore, while not shown, it will be readily appreciated that when the workpiece 120 has been partially processed such that the edge 122 of the workpiece 120 has been trimmed (see FIG. 3 of the present disclosure), the trimmed edge 122 of the workpiece 120 is protected by the fifth portion 202e of the buffer material 202 when inserted into the third bracket structure 106c. The first portion 202a and the third portion 202c similarly protect the trimmed edge 122 of the workpiece 120. In other words, the first, third, and fifth portions 202a, 202c, 202e of the buffer material 202 act as buffers that reduce an impact of the trimmed edge 122 of the workpiece 120 when the workpiece 120 slightly shifts within the FOUP 200.

As shown in FIG. 5C, the first, second, third, fourth, fifth, and sixth portions 202a, 202b, 202c, 202d, 202e, 202f of the buffer material 202 are separate and distinct from each other. In other alternative embodiments, respective and corresponding ones of the first, second, third, fourth, fifth, and sixth portions 202a, 202b, 202c, 202d, 202e, 202f are made of a single continuous piece of the buffer material 202. For example, in at least one embodiment, the first and second portions 202a, 202b of the buffer material 202 are instead made of a single continuous piece of the buffer material 202, the third and fourth portions 202c, 202d of the buffer material 202 are instead made of a single continuous piece of the buffer material 202, and the fifth and sixth portions 202e, 202f of the buffer material 202 are instead made of a single continuous piece of the buffer material 202.

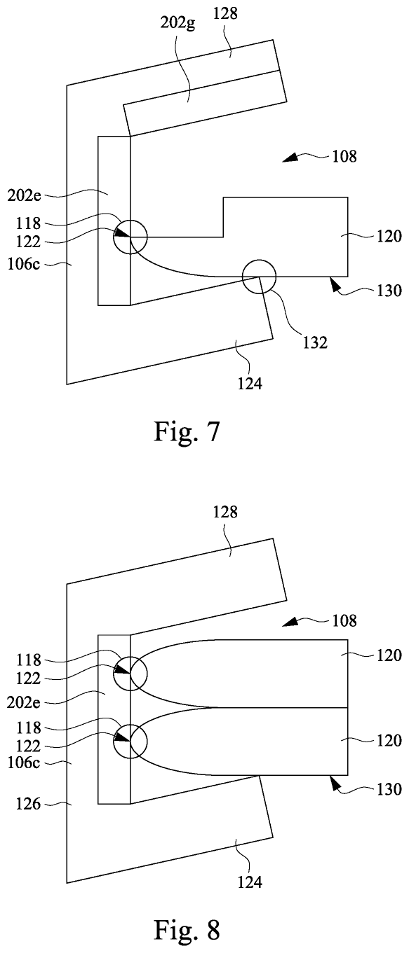

FIG. 7 is a zoomed in, enhanced view of section B-B as shown in FIG. 5C of a respective workpiece inserted into the corresponding recess 108 of the third bracket structure 106c of the FOUP 200 as shown in FIGS. 5A-5C. As shown in FIG. 7, the edge 122 of the workpiece 120, which is a slight processed trimmed wafer that has yet to undergo further processing steps within the FAB, abuts the third location 118 of the third bracket structure 106c. As the details of the third bracket structure 106c were described in detail earlier herein, the focus of the following discussion will be on additional, different, or new features with respect to the third bracket structure 106c as shown in FIG. 7 relative to FIG. 2.

As shown in FIG. 7, the fifth portion 202e of the sot material 202 is present at and along the side of the second portion 126 of the third bracket structure 106c. In other words, the fifth portion 202e of the buffer material 202 lines an interior surface or sidewall of the third bracket structure 106c at the third location 118. The fifth portion 202e of the buffer material 202 acts as a bumper material or portion that reduces an impact when the workpiece 120 is slightly shifted within the FOUP 200. A seventh portion 202g of the buffer material 202 is on the third portion 128 of the third bracket structure 106c. In other words, the seventh portion 202g of the buffer material 202 is on and along an interior surface or sidewall of the third portion 128 of the third bracket structure 106c.

While not shown, when the workpiece 120 is the same or similar to the respective workpiece 120 as shown in FIG. 4 that includes the first wafer 120a on which the second wafer 120b is stacked and coupled to, the seventh portion 202g of the buffer material 202 acts as a bumper material or portion that reduces an impact when the respective workpiece 120 including the first wafer 120a and the second wafer 120b is slightly shifted within the FOUP 200. The presence of the seventh portion 202g of the buffer material 202 reduces an impact between the surface 140 of the second wafer 120b and the third portion 128 of the third bracket structure 106c preventing or reducing the likelihood of mechanical defects propagating on, along, and within the respective workpiece 120 including the first wafer 120a and the second wafer 120b.

Unlike the embodiment of the third bracket structure 106c shown in FIG. 6, in the embodiment of the third bracket structure 106c shown in FIG. 7, the sixth portion 202f of the buffer material 202 is not present in this embodiment. However, in an alternative embodiment of the third bracket structure 106c, the sixth portion 202f of the buffer material 202 is provided along with the fifth portion 202e of the buffer material 202 and the seventh portion 202g of the buffer material 202.

While in FIG. 7 the fifth and seventh portions 202e, 202g of the buffer material 202 are shown as two separate and distinct pieces of the buffer material 202 that overlap with each other, in some alternative embodiments, the fifth and seventh portions 202e, 202g do not overlap with each other. In yet some other alternative embodiments, the fifth and seventh portions 202e, 202g are instead made of a single continuous piece of the buffer material 202.

FIG. 8 is a zoomed in, enhanced view of section B-B as shown in FIG. 5C of a respective workpiece inserted into the corresponding recess 108 of the third bracket structure 106c of the FOUP 200 as shown in FIGS. 5A-5C. As shown in FIG. 8, the edges 122 of the workpiece 120, which is an unprocessed stacked wafer assembly that has yet to undergo further processing steps within the FAB, abuts the third locations 118 of the third bracket structure 106c. As the details of the third bracket structure 106c were described in detail earlier herein, the focus of the following discussion will be on additional, different, or new features with respect to the third bracket structure 106c as shown in FIG. 8 relative to FIG. 2.

As shown in FIG. 8, the fifth portion 202e of the buffer material is present at and along the side of the second portion 126 of the third bracket structure 106c. In other words, the fifth portion 202e of the buffer material 202 lines an interior surface or sidewall of the third bracket structure 106c at the third locations 118. The fifth portion 202e of the buffer material 202 acts as a bumper material or portion that reduces an impact when the workpiece 120 is slightly shifted within the FOUP 200. A seventh portion 202g of the buffer material 202 is on the third portion 128 of the third bracket structure 106c. In other words, the seventh portion 202g of the buffer material 202 is on and along an interior surface or sidewall of the third portion 128 of the third bracket structure 106c.

While the first, second, third, and fourth portions 202a, 202b, 202c, 202d of the buffer material 202 are not shown in detail as the fifth, sixth, and seventh portions 202e, 202f, 202g, it will be readily appreciated that the first, second, third, and fourth portions 202a, 202b, 202c, 202d of the buffer material 202, in various embodiments, have the same functionality and purpose of preventing mechanical defects (e.g., scratching, micro-cracking, cracking, and other similar or like types of defects) by reducing impacts on the workpiece 120 when it slightly shifts within the FOUP 200 or reduces the likelihood of scratching on respective surfaces of the workpiece 120. For example, in at least some embodiments, these respective portions of the buffer material 202 look like those shown in FIGS. 6, 7, and 8. In other words, while not shown, the first and second bracket structures 106a, 106b have the same or similar structure of the third bracket structure 106c, as shown in FIGS. 6-8, and the first, second, third, and fourth portions 202a, 202b, 202c, 202d of the buffer material 202 have the same or similar structure along their corresponding brackets (i.e., the first bracket structure 106a and the second bracket structure 106b) and the first, second, third, and fourth portions 202a, 202b, 202c, 202d of the buffer material 202 are at respective locations of the corresponding first and second bracket structures 106a, 106b to prevent or reduce the likelihood of mechanical defects propagating at, along, or within the workpiece 120 when present within the FOUP 200.

While the various first, second, third, fourth, fifth, sixth, and seventh portions 202a, 202b, 202c, 202d, 202e, 202f, 202g of the buffer material 202 are shown in the respective positions in FIGS. 6-8, it will be readily appreciated that the buffer material 202 could be reoriented or repositioned at locations in which there is a high or highest likelihood of the workpiece 120 impacting the first, second, and third bracket structures 106a, 106b, 106c, or getting scratched due to slight shifts or movement of the workpiece 120 when present within the FOUP 200 due to external forces. In other words, the first, second, third, fourth, fifth, sixth, and seventh portions 202a, 202b, 202c, 202d, 202e, 202f, 202g are positioned to prevent or reduce the likelihood of mechanical defects propagating at, along, or within the workpiece 120 when within the FOUP 200.\

It will be readily appreciated that the various embodiments of the buffer material 202 at the various positions as shown in FIGS. 6, 7, and 8 is capable of being adjusted to receive any number of types of workpieces at various processing stages within the semiconductor manufacturing plant (FAB). Furthermore, it will be readily appreciated that any of the various embodiments as shown in FIGS. 6, 7, and 8 can be utilized for transferring any type of workpiece (e.g., the unprocessed or untrimmed workpiece 120 as shown in FIG. 6, the trimmed workpiece 120 as shown in FIG. 7, and the stacked workpiece 120 as shown in FIG. 8) as desired.

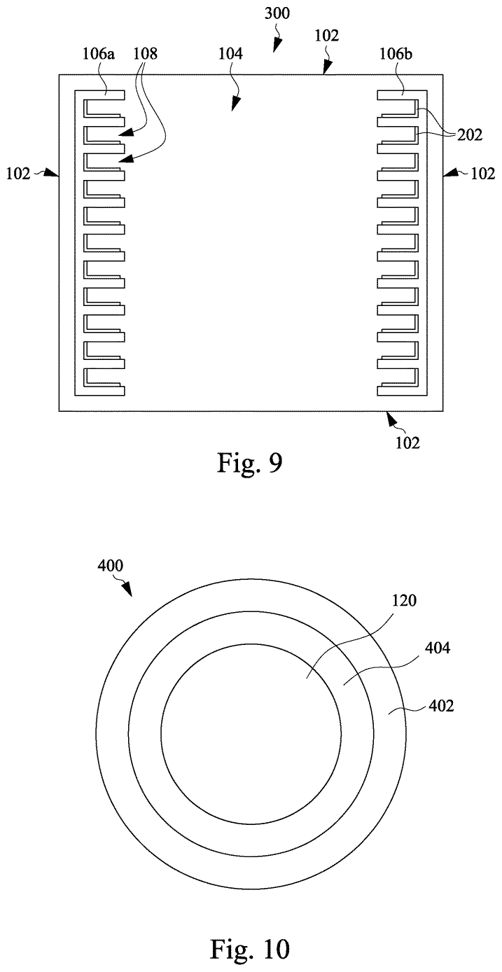

FIG. 9 is a cross-sectional view of a container 300, in accordance with some embodiments. The container 300 may be a FOUP or a cassette. In this alternative embodiment of the FOUP 300, the FOUP 300 includes the first bracket structure 106a and the second bracket structure 106b. While not shown, the FOUP 300 also includes the third bracket structure 106c. However, unlike the FOUP 200 in which only some of the recesses 108 of the first, second, and third bracket structures 106a, 106b, 106c are lined with the buffer material 202, in this alternative embodiment of the FOUP 300, all of the recesses 108 of the first, second, and third bracket structures 106a, 106b, 106c are lined with the buffer material 202. In view of this discussion, the respective bracket structures of various embodiments of FOUPs can be lined with the buffer material 202 as selected and desired to prevent or reduce the likelihood of mechanical defects propagating at, along, or within the respective workpieces 120 within the FOUP 300 depending on the type of the respective workpieces 120 to be placed within the FOUP 300.

FIG. 10 is a top plan view of a workpiece 400, which is a wafer assembly, that is capable of being inserted into the FOUPS 200, 300, in accordance with some embodiments. The workpiece 400, which is the wafer assembly, includes a frame 402, a tape 404, and the workpiece 120. An adhesive is present on a surface 406 of the tape 404. The adhesive is utilized to couple the tape 404 to a surface 408 of the frame 402. The tape 404 is coupled to the surface 130 of the workpiece 120 by the adhesive as well. The workpiece 120 is spaced inward from the frame 402 and the workpiece 120 is surrounded by the frame 402.

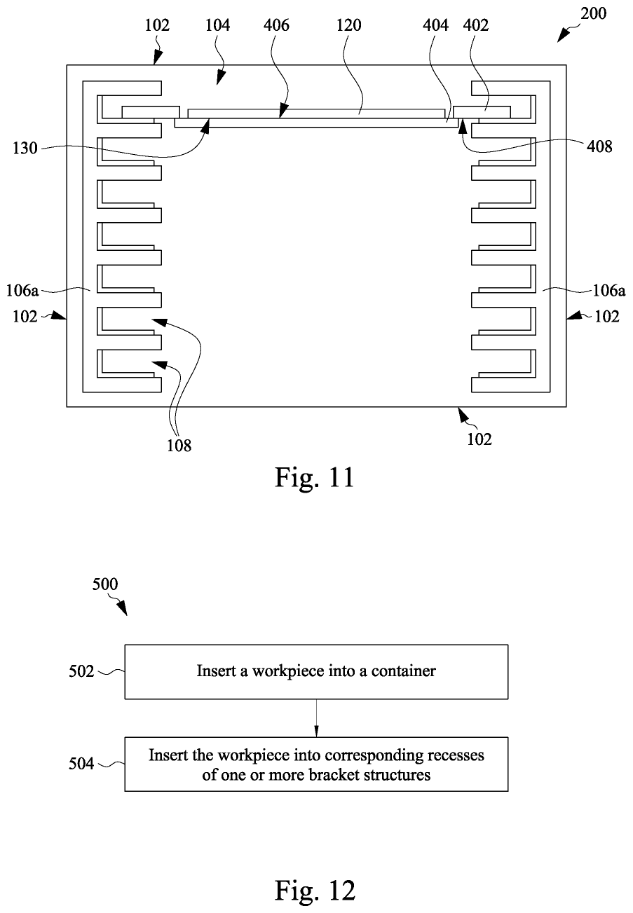

FIG. 11 is a cross-sectional view of the workpiece 400, which is the wafer assembly, inserted into corresponding recesses 108 of the first, second, and third bracket structures 106a, 106b, 106c within the cavity 104 of the FOUP 300, in accordance with some embodiments. The frame 402 of the workpiece 400 is inserted into the recesses 108 instead of the workpiece 120 itself. Inserting the frame 402 into the corresponding recesses 108 of the first, second, and third bracket structures 106a, 106b, 106c of the FOUP 300 prevents the workpiece 120 from impacting the first, second, and third bracket structures 106a, 106b, 106c and prevents the surface 130 from being scratched by the first, second, and third bracket structures 106a, 106b, 106c. In other words, the frame 402 along with the tape 404 act as a support or retainer to prevent the workpiece 120 from physically contacting or abutting the first, second, and third bracket structures 106a, 106b, 106c when the workpiece 400 is positioned within the FOUP 300. As shown in FIG. 11, the frame 402 of the workpiece 400 is positioned on the buffer material 202 within the corresponding recesses 108 of the first, second, and third bracket structures 106a, 106b, 106c. As the frame 402 of the workpiece 400 is positioned on the buffer material 202 within the corresponding recesses 108 of the first, second, and third bracket structures 106a, 106b, 160c, the buffer material 202 acts as non-slip feature to prevent the frame 402 from shifting or moving when positioned within the corresponding recesses 108 of the first, second, and third bracket structures 106a, 106b, 106c.

FIG. 12 is a flowchart 500 of a method of utilizing the FOUPs 200, 300, in accordance with some embodiments. The flowchart 500 includes a first step 502 and a second step 504. While the following discussion will be with respect to a method of utilizing the FOUP 200 including the third bracket structure 106c lined with the buffer material 202 as shown in FIG. 6, it will be readily apparent that the following discussion can be readily applied and adapted to be applied to utilizing the respective embodiments of the FOUPs 200, 300 and the various embodiments of the buffer material 202 lining the third bracket structure 106c as shown in FIGS. 7 and 8.

In the first step 502, the workpiece 120 is inserted into the cavity 104 of the FOUP 200 through the opening (not shown). The workpiece 120 is inserted into the cavity 104 through the opening by, for example, a TRA (i.e., transfer robot arm).

In a second step 504, the workpiece 120 is then inserted into corresponding recesses 108 of the first bracket structure 106a, the second bracket structure 106b, and the third bracket structure 106c. When the workpiece 120 is inserted into these corresponding recesses 108 of the first, second, and third bracket structures 106a, 106b, 106c, the workpiece 120 is positioned onto and physically abuts the second, fourth, and sixth portions 202b, 202d, 202f of the buffer material 202. For example, in at least one embodiment, once the workpiece 120 is resting within the corresponding recesses 108 of the first, second, and third bracket structures 106a, 106b, 106c, the surface 130 of the workpiece 120 is resting on the second, fourth, and sixth portions 202b, 202d, 202f of the buffer material 202. Alternatively, in some embodiments, the edge 122 of the workpiece 120 rests on at least one of the second, fourth, and sixth portions 202b, 202d, 202f of the buffer material 202. Alternatively, in some embodiments, the edge 122 of the workpiece 120 rests on all of the second, fourth, and sixth portions 202b, 202d, 202f.

In this second step 504, when the workpiece 120 is inserted into the corresponding recesses 108 of the first, second, and third bracket structures 106a, 106b, 106c and the workpiece 120 is slightly misaligned when being inserted such that the edge 122 of the workpiece 120 physical abuts against at least one of the first, third, and fifth portions 202a, 202c, 202e of the buffer material 202, the at least one of the first, third, and fifth portions 202a, 202c, 202e of the buffer material 202 acts as a bumper material or portion reducing an impact on the edge 122 of the workpiece 120 preventing or reducing the likelihood of mechanical defects propagating at, along, or within the workpiece 120.

The first and second steps 502, 504 may be repeated multiple times in succession to fill the recesses 108 of the first, second, and third bracket structures 106a, 106b, 106c with a plurality of the workpieces 120. In some situations, the first and second steps 502, 504 may be repeated multiple times in succession to only partially fill the recesses 108 of the first, second, and third bracket structures 106a, 106b, 106c within the FOUP 200. In other words, any number of the workpieces 120 are inserted into the recesses 108 of the first, second, and third bracket structures 106a, 106b, 106c as desired or selected.

After the second step 504, the TRA previously utilized to insert the workpiece 120 into the corresponding recesses 108 of the first, second, and third bracket structures 106a, 106b, 106c is removed through the opening of the FOUP 200, and a door or lid structure (not shown) of the FOUP 200 is closed to close off the opening and seal the workpiece 120 within the cavity 104 of the FOUP 200. The FOUP 200 containing the workpiece 120 may then be transported to a selected location within the FAB by, for example, an OHT (i.e., overhead transport vehicle).

While not discussed in detail, the first and second steps 502, 504 of the flowchart 500 can be performed in a reversed manner to remove the workpiece 120 from the FOUP 200. For the sake of simplicity and brevity of the present disclosure, removing the workpiece 120 from the FOUP 200 is not discussed in detail readily herein but should become readily apparent in how this is performed based on the discussion of the flowchart 500 as set earlier herein.

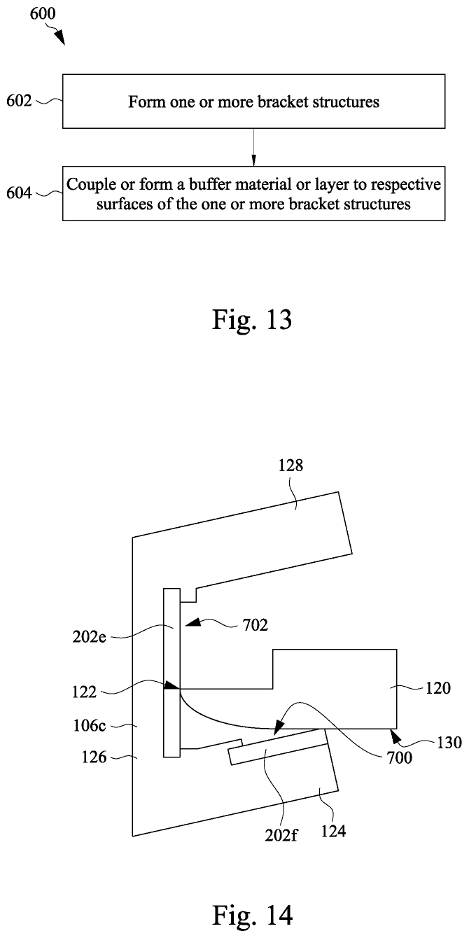

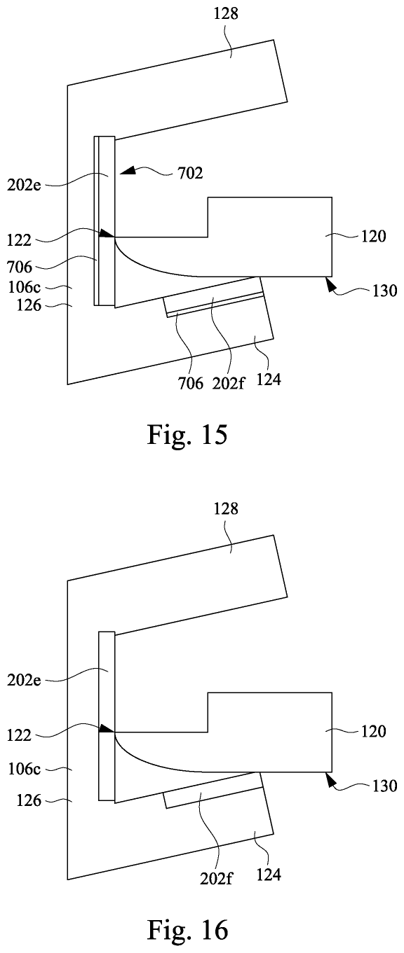

FIG. 13 is a flowchart 600 of a method of manufacturing the various embodiments of the one or more bracket structures 106a, 106b, 106c as discussed herein. The flowchart 600 includes a first step 602 and a second step 604. In the first step 602, the one or more bracket structures 106a, 106b, 106c are manufactured. For example, in at least one embodiment, when the one or more bracket structures 106a, 106b, 106c are made of a metal material, the one or more bracket structures 106a, 106b, 106c are milled or manufactured with some other suitable technique for forming the one or more bracket structures 106a, 106b, 106c from metal. Alternatively, for example, in at least one embodiment, when the one or more bracket structures 106a, 106b, 106c are made of a plastic material, the one or more bracket structures 106a, 106b, 106c are injected molded or manufactured with some other suitable technique for forming the one or more bracket structures 106a, 106b, 106c from the plastic material. After the first step 602 in which the one or more bracket structures 106a, 106b, 106c are formed, in the second step 604 the buffer material or layer 202 is coupled to (see FIGS. 14 and 15) or formed on (see FIG. 16) respective surfaces or regions of the one or more bracket structures 106a, 106b, 106c. The following discussions with respect to FIGS. 14-16 will focus on forming a single one of the bracket structure 106c, but it will be readily appreciated that the following discussions can readily apply to forming any number of the one or more bracket structures 106a, 106b, 106c.

As shown in FIGS. 14 and 15, in some embodiments of manufacturing the one or more bracket structures 106a, 106b, 106c lined with the buffer material 202, a first recessed region 700 is formed along a respective surface of the first portion 124 of the bracket structure 106c, and a second recessed region 702 is formed along a respective surface of the second portion 126. The first recessed region 700 and the second recessed region 702 are formed during the first step 602 of the flowchart 600 in manufacturing the bracket structure 106c.

As shown in FIG. 14, after the bracket structure 106c has been formed, in some embodiments of manufacturing the one or more bracket structures 106a, 106b, 106c lined with the buffer material 202, the fifth portion 202e of the buffer material 202 is coupled to the bracket structure 106c along or within the second recessed region 702, and the sixth portion 202f of the buffer material 202 is coupled to the bracket structure 106c along or within the first recessed region 700. While note shown in FIG. 14 for sake of simplicity of FIG. 14, these respective portions (i.e., the fifth portion 202e and the sixth portion 202f) of the buffer material 202 are coupled to the bracket structure 106c by snap fit fasteners or some other suitable type of fastener such that the respective portions of the buffer material are held in place along or within the first and second recessed regions 700, 702, respectively.

In an alternative manufacturing method, as shown in FIG. 15, after the bracket structure 106c has been formed, in some embodiments of manufacturing the one or more bracket structures 106a, 106b, 106c lined with the buffer material 202, the fifth portion 202e of the buffer material 202 is coupled to the bracket structure 106c along or within the second recessed region 702, and the sixth portion 202f of the buffer material 202 is coupled to the bracket structure 106c along or within the first recessed region 700. These respective portions (i.e., the fifth portion 202e and the sixth portion 202f) of the buffer material 202 are coupled to the bracket structure 106c by an adhesive 706 such that the respective portions of the buffer material are held in place along or within the first and second recessed regions 700, 702, respectively. For example, in some embodiments, the adhesive 706 and the buffer material 202 on the adhesive 706 is a tape including a layer of the adhesive 706 and a layer of the buffer material 202.

In an alternative manufacturing method, as shown in FIG. 16, after the bracket structure 106c has been formed, in some embodiments of manufacturing the one or more bracket structures 106a, 106b, 106c lined with the buffer material 202, the fifth portion 202e of the buffer material 202 is coupled to the bracket structure 106c along or within the second recessed region 702, and the sixth portion 202f of the buffer material 202 is coupled to the bracket structure 106c along or within the first recessed region 700. These respective portions (i.e., the fifth portion 202e and the sixth portion 202f) of the buffer material 202 are directly deposited or formed onto the bracket structure 106c such that the respective portions of the buffer material 202 are deposited and formed in place along or within the first and second recessed regions 700, 702, respectively In some embodiments, when the buffer material 202 is deposited or formed onto the bracket structure 106c, the buffer material is permanently attached to the respective surfaces on which the buffer material 202 is deposited or formed.

Unlike the embodiment as shown in FIG. 16 in which the buffer material 202 is deposited or formed onto the respective surfaces such that in some embodiments the buffer material 202 is permanently adhered to the respective surfaces of the bracket structure 106c, in the embodiments as shown in FIGS. 14 and 15, the buffer material 202 is capable of be removed and replaced. For example, when the buffer material 202 is coupled to the bracket structure 106c by the snap fasteners, the old buffer material 202 can be removed and replaced with new buffer material 202 by utilizing respective snap fasteners to remove the old buffer material 202 and attached new buffer material 202 with respective snap fasteners. Alternatively, a similar process can be performed when there are fasteners (i.e., screws, nuts and bolts, or some other suitable type of fastener) instead of snap fit fasteners to couple the buffer material 202 to the bracket structure 106c. Also, for example, when the buffer material 202 is coupled to the bracket structure 202 by the adhesive 706, the old buffer material 202 can be peeled off the respective surfaces of the bracket structure 106c and replaced with new buffer material 202 by applying more of the adhesive 706 and then attached the buffer material 202 to the bracket structure 202.

As the embodiment in FIG. 14 utilizes the snap fit fasteners to couple the buffer material 202 to the bracket structure 106c, there is less of a chance of contaminants being exposed to the workpiece 120 relative to the other embodiments as shown in FIGS. 15 and 16 as there are fewer materials or chances for those materials to be mis-formed or mis-deposited.

As set forth herein and above, the FOUPs 200, 300 with the first, second, and third bracket structures 106a, 106b, 106c that have at least some of the recesses 108 lined with the buffer material 202 prevent or reduce the likelihood of mechanical defects (e.g., scratching, micro-cracking, cracking or other similar or like types of mechanical defects) propagating at, along, or within respective workpieces when stored within the FOUPs 200, 300. This is because the buffer material 202 acts as bumper material and a non-slip feature. By preventing or reducing the propagation of mechanical defects in respective workpieces when within the FOUPs 200, 300, a yield number output by a FAB (i.e., semiconductor manufacturing plant) is increased, and, in turn, increases profit and efficiency.

At least one embodiment of a container of the present disclosure is summarized as including: a plurality of sidewalls; one or more bracket structures within the cavity, each respective bracket structure of the one or more bracket structures includes a plurality of recesses configured to, in operation, receive a corresponding plurality of workpieces; and a buffer material in at least one of the plurality of recesses of each respective bracket structure of the one or more bracket structures.

At least one embodiment of a bracket structure within a workpiece container of the present disclosure is summarized as including: a first portion extending in a first direction; a second portion extending in the first direction and spaced apart from the first portion; a third portion extending from the first portion to the second portion, the third portion extends in a second direction transverse to the first direction, and the third portion couples the first portion to the second portion; a recess defined by the first portion, the second portion, and the third portion, the recess configured to, in operation, receive a workpiece; and a buffer material within the recess.

At least one embodiment a method of the present disclosure is summarized as including: inserting a workpiece into a cavity of a workpiece container; and inserting the workpiece into a first recess of a first bracket structure at least partially lined with a buffer material, the first bracket structure being present within the cavity of the workpiece container.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A container, comprising:
a plurality of sidewalls;
one or more bracket structures within the cavity, each respective bracket structure of the one or more bracket structures includes a plurality of recesses configured to, in operation, receive a corresponding plurality of workpieces; and
a buffer material in at least one of the plurality of recesses of each respective bracket structure of the one or more bracket structures.

2. The container of claim 1, wherein the one or more bracket structures include:
a first bracket structure in close proximity to a first sidewall of the plurality of sidewalls;
a second bracket structure in close proximity to a second sidewall of the plurality of sidewalls, the second sidewall being opposite to the first sidewall; and
a third bracket structure in close proximity to a third sidewall of the plurality of sidewalls, the third sidewall is between the first sidewall and the second sidewall.

3. The container of claim 1, wherein the buffer material is at least one of the following of a material with a hardness less than that of the one or more bracket structures or a Young's modulus or elastic coefficient less than that of the one or more bracket structures.

4. The container of claim 1, wherein the buffer material includes a first portion and a second portion within the at least one of the plurality of recesses of each respective bracket structure of the one or more bracket structures.

5. The container of claim 4, wherein the first portion and the second portion of the buffer material are distinct and separate from each other.

6. The container of claim 1, wherein the one or more bracket structures is made of at least one of the following of a metal material, an alloy material, or a plastic material, and the buffer material is selected from at least one of the following of a tape, a rubber material, a polytetrafluoroethylene (PTFE) material, a polymer compound material, a leather material, or a foam material.

7. A bracket structure within a workpiece container, comprising:
a first portion extending in a first direction;
a second portion extending in the first direction and spaced apart from the first portion;
a third portion extending from the first portion to the second portion, the third portion extends in a second direction transverse to the first direction, and the third portion couples the first portion to the second portion;
a recess defined by the first portion, the second portion, and the third portion, the recess configured to, in operation, receive a workpiece; and
a buffer material within the recess.

8. The bracket structure within the workpiece container of claim 7, wherein the buffer material includes:
a support portion at an end of the first portion, the support portion is configured to, in operation, have the workpiece rest on the support portion; and
a bumper portion along an interior sidewall of the third portion, the bumper portion is configured to, in operation, cushion the workpiece when impacting the bumper portion.

9. The bracket structure of claim 8, wherein the support portion is configured to, in operation, act as a non-slip feature to prevent shifts in a position of the workpiece when within the recess.

10. The bracket structure within the workpiece container of claim 7, wherein the buffer material includes:
a first bumper portion along a first interior sidewall of the third portion, the first bumper portion configured to, in operation, cushion the workpiece when impacting the first bumper portion; and
a second bumper portion along a second interior sidewall of the second portion, the second bumper portion configured to, in operation, cushion the workpiece when impacting the second bumper portion.

11. The bracket structure of claim 10, wherein the second bumper portion is transverse to the first bumper portion.

12. The bracket structure within the workpiece container of claim 7, wherein the buffer material includes:
a bumper portion along an interior sidewall of the third portion, the bumper portion configured to, in operation, cushion the workpiece when impacting the bumper portion.

13. The bracket structure within the workpiece container of claim 7, wherein the recess is one recess of a plurality of recesses.

14. The bracket structure within the workpiece container of claim 13, wherein at least one recess of the plurality of recesses is devoid of the buffer material.

15. The bracket structure of claim 14, wherein:
the workpiece is a first type of workpiece;
the at least one recess devoid of the buffer material is configured to, in operation, receive a second type of workpiece different from the first type of workpiece; and
the recess in which the buffer material is present is configured to, in operation, receive the workpiece of the first type.

16. A workpiece container, comprising:
a plurality of sidewalls defining a cavity;
a first bracket structure within the cavity in close proximity to a first sidewall of the plurality of sidewalls, the first bracket structure including a plurality of recesses configured to, in operation, receive a corresponding plurality of workpieces;
a second bracket structure within the cavity in close proximity to a second sidewall of the plurality of sidewalls, the second sidewall being opposite to the first sidewall, the second bracket structure including a plurality of recesses configured to, in operation, receive the corresponding plurality of workpieces; and
a buffer material in at least one recess of the plurality of recesses of the first bracket structure and in at least one recess of the plurality of recesses of the second bracket structure, the buffer material including a support portion configured to, in operation, have a workpiece of the corresponding plurality of workpieces rest on the support portion, and a bumper portion configured to, in operation, cushion the workpiece when impacting the bumper portion.

17. The workpiece container of claim 16, further comprising:
a third bracket structure within the cavity in close proximity to a third sidewall of the plurality of sidewalls, the third sidewall being between the first sidewall and the second sidewall, the third bracket structure including a plurality of recesses configured to, in operation, receive the corresponding plurality of workpieces, at least one recess of the plurality of recesses of the third bracket structure being at least partially lined with the buffer material.

18. The workpiece container of claim 16, wherein the support portion is at an end of a first portion of the first bracket structure defining the at least one recess, and the bumper portion is along an interior sidewall of a third portion of the first bracket structure defining the at least one recess, the third portion extending in a direction transverse to the first portion.

19. The workpiece container of claim 16, wherein the support portion is configured to, in operation, act as a non-slip feature to prevent shifts in a position of the workpiece when within the at least one recess.

20. The workpiece container of claim 16, wherein at least one recess of the plurality of recesses of the first bracket structure is devoid of the buffer material, the at least one recess devoid of the buffer material being configured to, in operation, receive a second type of workpiece different from a first type of workpiece received by the at least one recess in which the buffer material is present.
